(19) United States
(12) Patent Application Publication
(10) Pub. No.: US 2026/0095680 A1
(43) Pub. Date: Apr. 2, 2026

(54) AUTOMATIC CONVERSION GAIN SELECTION ADC FOR IMAGE SENSORS

(71) Applicant: Apple Inc., Cupertino, CA (US)

(72) Inventors: Rituraj Singh, Los Gatos, CA (US); Ashirwad Bahukhandi, Los Gatos, CA (US)

(21) Appl. No.: 18/900,606

(22) Filed: Sep. 27, 2024

(51) Int. Cl. H04N 25/51; H03M 1/06; H04N 23/667; H04N 25/587; H04N 25/621; H04N 25/76; H04N 25/77; H04N 25/78

(52) U.S. Cl. CPC H04N 25/51; H03M 1/0604; H04N 23/667; H04N 25/587; H04N 25/621; H04N 25/77; H04N 25/7795; H04N 25/78

(57) ABSTRACT

Embodiments are disclosed for an automatic conversion gain selection ADC (“ACGS-ADC”) for image sensors. In some embodiments, the ACGS-ADC comprises: a comparator to compare a reference signal and a pixel signal readout from a high dynamic range (HDR) pixel in accordance with a selected conversion gain mode; a counter coupled to the output of the comparator and to a clock, the counter to start counting in response to the output of the comparator and the clock, the counter outputting a digital representation of the pixel signal; and a logic block coupled to selection circuitry of the HDR pixel, the logic block to compare output of the comparator to a limit or threshold and generate at least one feedback signal for configuring conversion gain selection circuitry of the HDR pixel based on whether the output of the comparator exceeds the saturation limit or threshold value.

### TECHNICAL FIELD

This disclosure relates generally to image sensors, and in particular to an intelligent per-pixel control of conversion gain to enable high frame-rate high dynamic range (HDR) image sensors.

### BACKGROUND

Mobile device cameras (e.g., smartphone cameras) are becoming more sophisticated and closing the gap with professional film making equipment. One highly desired feature in smartphone cameras is HDR imaging, which is the ability to preserve details in both bright and dark regions in a single image. The higher the dynamic range of the sensor, the higher the ratio of the brightest pixel value to the darkest pixel value that the sensor can handle without saturation. An example of a high dynamic range scene is an image of a bright sky along with a dark shadow with a contrast ratio as high as 10⁵.

While algorithmic and machine learning-based solutions exist for HDR enhancement of still images, a true high image quality video HDR remains elusive. Conventional image sensors implement HDR imaging by utilizing a HDR pixel with programmable conversion gain (CG). Typically, there are two or three programmable conversion gains available inside a HDR pixel commonly referred to as dual conversion gain (DCG) and triple conversion gain (TCG) pixels, respectively. Conventional pixel operation for HDR readout employs a brute-force approach of sequencing through the pixel conversion gains and utilizing an analog-to-digital converter (ADC) to digitize pixel output at each conversion gain setting. This approach is time consuming and as a result cannot achieve a high video frame rate.

### SUMMARY

Embodiments are disclosed for an automatic conversion gain selection ADC for image sensors.

In some embodiments, a method comprises: resetting a photodetector of a high dynamic range (HDR) pixel to start a new exposure of the HDR pixel; accumulating charge on the photodetector; performing a first conversion gain reset of at least one floating diffusion node; sampling and storing a first reset level at a pixel output node; performing a second conversion reset of the at least one floating diffusion node; sampling and storing a second reset level at the pixel output node; transferring charge from the photodetector to the at least one floating diffusion node; sampling a pixel signal level at the pixel output node; comparing the sampled pixel signal level to a threshold value; selecting a conversion gain mode based on the comparing; configuring circuitry of the HDR pixel based on the selected conversion gain mode; reading out the pixel signal level at the pixel output node; compensating the pixel signal level using one of the first reset level or the second reset level in accordance with the selected conversion gain mode; and generating a digital representation of the compensated pixel signal level.

In some embodiments, the HDR pixel is a dual conversion gain (DCG) pixel and the threshold value is an arbitrary set value or a saturation limit of the photodetector.

In some embodiments, the HDR pixel is a dual conversion gain (DCG) pixel and the threshold value is a saturation limit of the photodetector.

In some embodiments, selecting a conversion gain mode based on the comparing further comprises: inputting the sampled pixel signal into an analog-to-digital converter (ADC) that includes a comparator for comparing the sampled pixel signal with a reference signal level; determining that an output of the comparator is greater than the saturation limit; and generating a feedback signal for the HDR pixel, the feedback signal configuring circuity in the HDR pixel to select a low conversion gain (LCG) mode.

In some embodiments, the ADC is a ramp-type ADC and the method further comprises: determining a comparator flip error; and compensating for the comparator flip error.

In some embodiments, the method further comprises generating gain bits to be appended with the digital representation during the LCG mode to extend the dynamic range and quantization resolution of an image sensor.

In some embodiments, non-readout rows of the pixel are kept in anti-blooming configuration to avoid impact from toggling of a shared column of the pixel.

In some embodiments, the HDR pixel is a triple conversion gain (TCG) pixel with three conversion gain modes, including a low conversion gain (LCG) mode, a high conversion gain (HCG) mode and a LOFIC conversion gain mode, and wherein the TCG pixel performs two sequential readouts of the pixel signal level.

In some embodiments, the HDR pixel is a triple conversion gain (TCG) pixel with three conversion gain modes, including a low conversion gain (LCG) mode, a medium conversion gain (MCG) mode and a high conversion gain (HCG) mode, and wherein the TCG pixel performs two sequential readouts of the pixel signal level.

In some embodiments, selecting a conversion gain mode based on the comparing further comprises: inputting the sampled pixel signal into an analog-to-digital converter (ADC) that includes a comparator for comparing the sampled pixel signal with a reference signal level; determining that an output of the comparator is greater than a specified threshold; and generating two feedback signals for the HDR pixel, the two feedback signals configuring circuitry in the HDR pixel to select one of the LCG, HCG or LOFIC conversion gain mode.

In some embodiments, the circuitry of the HDR pixel is configured to readout a LOFIC pixel signal, followed by a readout of a LOFIC reset level, followed by a readout of a LCG reset level, followed by a readout of a LCG pixel signal.

In some embodiments, the circuitry of the HDR pixel is configured to readout a sampled LCG reset level, followed by a readout of a HCG reset level, followed by a readout of a HCG pixel signal, followed by a readout of a LCG pixel signal.

In some embodiments, the circuitry of the HDR pixel is configured to readout a LCG signal level, followed by a LCG reset level, followed by a readout of a MCG reset level, followed by a readout of an MCG pixel signal.

In some embodiments, the circuitry of the HDR pixel is configured to readout a sampled MCG reset level, followed by a readout of a HCG reset level, followed by a readout of a HCG pixel signal, followed by a readout of an MCG pixel signal.

In some embodiments, an analog-to-digital converter (ADC) comprises: a reference signal generator configured to generator a reference signal; a clock pulse generator configured to generate a clock; a comparator configured to compare the reference signal and a pixel signal readout from a high dynamic range (HDR) pixel, where the HDR pixel has a low conversion gain (LCG) mode and a high conversion gain (HCG) mode; a counter coupled to the output of the comparator and to the clock, the counter configured to start counting in response to the output of the comparator and the clock, the counter outputting a digital representation of the pixel signal; and a logic block configured to compare the output of the comparator to a saturation limit of the HDR pixel and generate a feedback signal to the HDR pixel, the feedback signal for configuring circuitry of the HDR pixel to select one of the HCG mode or the LCG mode based on whether the output of the comparator exceeds the saturation limit.

In some embodiments, the reference signal generator is a ramp generator and the reference signal is a ramp signal.

In some embodiments, an analog-to-digital converter (ADC) comprises: a reference signal generator configured to generate a reference signal; a clock pulse generator configured to generate a clock; a comparator configured to compare the reference signal and a pixel signal readout from a high dynamic range (HDR) pixel, where the HDR pixel has a low conversion gain (LCG) mode, a high conversion gain (HCG) mode and a lateral overflow integrating capacitor (LOFIC) conversion mode, and the pixel signal is a sampled LOFIC signal; a counter coupled to the output of the comparator and to the clock, the counter configured to start counting in response to the output of the comparator and the clock, the counter outputting a digital representation of the pixel signal; and a logic block configured to compare the output of the comparator to a threshold value and generate two feedback signals to the HDR pixel, the two feedback signals for configuring circuitry of the HDR pixel to select one of the HCG mode, the LCG mode or the LOFIC mode based on whether the output of the comparator exceeds the threshold value.

In some embodiments, the two feedback signals configure circuitry in the HDR pixel to select one of two ADC readout sequences, a first readout sequence comprising: readout of a LOFIC signal, followed by readout of a LOFIC reset level, followed by readout of an LCG reset level, followed by readout of an LCG signal, and a second readout sequence comprising: readout of an LCG reset level, followed by readout of an HCG reset level, followed by readout of an HCG signal, followed by readout of an LCG signal.

In some embodiments, the logic block generates a bit indicating the selected ADC readout sequence.

In some embodiments, an image sensor comprises: a pixel array comprising rows and columns of high dynamic range (HDR) pixels, each HDR pixel including circuitry for processing charge accumulated on a photodiode of the HDR pixel when exposed to light and selection circuitry for selecting one of at least two conversion gain modes for readout of the HDR pixels; readout circuitry configured to readout each column of the pixel array by selecting each row of the pixel array in a sequence in accordance with the selected conversion gain mode; an analog-to-digital converter (ADC) coupled to each column of the pixel array, each ADC comprising: a comparator configured to compare a reference signal and a pixel signal readout from an HDR pixel in accordance with the selected conversion mode; a counter coupled to the output of the comparator and to the clock, the counter configured to start counting in response to the output of the comparator and the clock, the counter outputting a digital representation of the pixel signal; and a logic block coupled to selection circuitry of the HDR pixel, the logic block configured to compare the output of the comparator to a saturation limit or threshold value and to generate at least one feedback signal to the HDR pixel for configuring the selection circuitry of the HDR pixel based on whether the output of the comparator exceeds the saturation limit or threshold value.

Particular embodiments described herein provide one or more of the following advantages. The disclosed embodiments implement an intelligent ADC which can self-determine the optimal conversion gain to pick for the pixel being read out. The ADC sets the optimal conversion gain and therefore does not waste time reading a non-optimal conversion gain, which contains/graded/or low signal-to-noise (SNR) information. The embodiments overcome the challenge to build such intelligence in a small form factor of a <1 μm image sensor pixel. The disclosed embodiments implement a novel pixel routing scheme and logic partitioning between pixel and column ADC to implement the routing scheme. The disclosed embodiments can utilize existing pixel circuit topologies with minimal rerouting.

### BRIEF DESCRIPTION OF THE DRAWINGS

FIG. 1 is schematic diagram of an auto CG-select ADC (“ACGS-ADC”) for a dual conversion gain (DCG) pixel architecture, according to one or more embodiments.

FIG. 2 is a timing diagram for the ACGS-ADC shown in FIG. 1, according to one or more embodiments.

FIG. 3 is an ADC readout sequence diagram corresponding to the schematic in FIG. 1 and timing diagram shown in FIG. 2, according to one or more embodiments.

FIG. 4 illustrates the pixel SNR versus scene illumination diagram for a DCG pixel with dual exposure overlaid with and an error correction mechanism for ACGS-ADC utilizing ramp overlap, according to one or more embodiments.

FIG. 5 is schematic diagram of an ACGS-ADC for a triple conversion gain (TCG) pixel architecture, according to one or more embodiments.

FIG. 6 is a timing diagram for the ACGS-ADC shown in FIG. 5, according to one or more embodiments.

FIG. 7 is an ADC readout sequence diagram corresponding to the schematic in FIG. 5 and timing diagram shown in FIG. 6, according to one or more embodiments.

FIG. 8 illustrates the pixel SNR versus scene illumination diagram for a TCG pixel operation, according to one or more embodiments.

FIG. 9 is schematic diagram of an ACGS-ADC for an alternative TCG pixel architecture, according to one or more embodiments.

FIG. 10 is a timing diagram for the ACGS-ADC shown in FIG. 9, according to one or more embodiments.

FIG. 11 is an ADC readout sequence diagram corresponding to the schematic in FIG. 9 and timing diagram shown in FIG. 10, according to one or more embodiments.

FIG. 12 illustrates a process of adaptive CG, according to one or more embodiments.

FIG. 13 is a block diagram of an example device architecture for implementing the features and processes described in reference to FIGS. 1-12.

### DETAILED DESCRIPTION

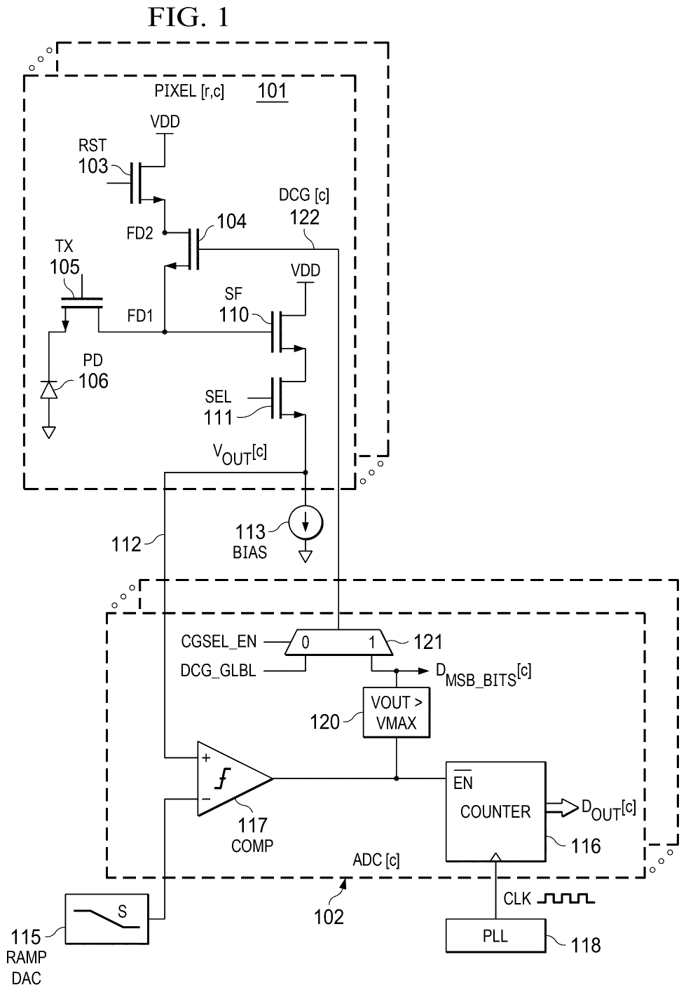

FIG. 1 is schematic diagram of a column-level ACGS-ADC 102 for a DCG pixel architecture, according to one or more embodiments. ACGS-ADC 102 is shown coupled to the output node 112 of pixel 101. In the example shown, only a single pixel 101 and ACGS-ADC 102 are shown. A CMOS image sensor, however, comprises a two-dimensional array of pixels 101 arranged in rows and columns. The image sensor includes analog “readout” circuitry (not shown) that is configured to readout each column [c] of pixels by selecting the individual rows [r] of the column [c] in an ordered sequence. Each column [c] is coupled to its own ACGS-ADC 102 for converting the analog output voltage (Vₒᵤₜ) at pixel output node 112 to a digital representation that is processed in the digital domain by, e.g., an image signal processor (ISP). Note that the specific sequence of conversion gain readout described in the embodiments below are examples. In other embodiments, the order of conversion gain readout can be different.

Pixel 101 includes reset transistor (RST) 103, DCG transistor 104, transfer gate (TX) 105, photodetector (PD) 106 (e.g., a photodiode), first floating diffusion node FD1, second floating diffusion node FD2, source follower (SF) 110, row selection (SEL) transistor 111, pixel output node 112, current source 113. In some embodiments, an optional in-pixel capacitor can be coupled to node FD2 to increase the equivalent capacitance at node FD2.

TX 105 is used to transfer charge across PD 106 to node FD1. DCG 104 is used to control the pixel conversion gain. When DCG 104 is deactivated, high conversion gain (HCG) is defined by the equivalent capacitance at node FD1. Note that CG is the inversely proportional to the equivalent capacitance of node FD1. Capacitance, C, is the ratio of the amount of charge, Q, required to change the potential of a node, V, by one volt (C=Q/V), which means that, as the capacitance of node FD1 increases, the CG (and therefore the sensitivity) of node FD1 decreases. When DCG 104 is activated, low conversion gain (LCG) is defined by the sum of equivalent capacitances at nodes FD1 and FD2.

RST 103 is used to reset PD 106 and node FD1. SF 110 buffers node FD1 and drives pixel output node 112. SEL 111 connects SF 110 to pixel output node 112. Typically, pixel output node 112 is a shared readout line for pixels in the same column in the pixel array. Current source 113 provides bias current for SF 110 and can be placed outside of the pixel array and shared for all pixels in the same column.

ACGS-ADC 102 includes ramp generator 115, counter 116, logic 117, and clock pulse generator 118, which are simultaneously operated to provide analog-to-digital conversion. Two inputs are provided to logic 117. These inputs include Vₒᵤₜ from pixel output node 112 and a linear ramp (e.g., a sawtooth) voltage from ramp generator 115. The output of ramp generator 115 (a reference signal) is initiated each time the enable input (E̅N̅) of counter 116 is asserted. That is when E̅N̅=0, counter 116 increments with the clock provided by clock pulse generator 118. When E̅N̅=1, the output of counter 116 freezes.

When the analog and ramp generator inputs to logic 117 differ in magnitude, counter 116 is enabled (E̅N̅=0) and clock pulse generator 118 (e.g., a phase locked loop (PLL) circuit) is permitted to transmit pulses at a constant repetition rate to counter 116. When the two inputs to logic 117 become equal (as a result of the linearly rising sawtooth), logic 117 generates a stop signal which disables counter 116 (E̅N̅=1) and ends the comparison time interval. The number of pulses accumulated in counter 116 during the comparison time interval is proportional to the amplitude of Vₒᵤₜ. The output of counter 116 indicates the desired digital representation for the column c (Dₒᵤₜ[c]) after compensating the pixel output voltage V₀ by subtracting the stored reset level from the pixel output voltage using, e.g., correlated double sampling (CDS) in the digital domain.

Although in this example a ramp-type (single slope) ADC was used, other column-level ADCs can be used including but not limited to a cyclic ADC or a successive-approximation-register (SAR) ADC.

### Conventional Operation

For HCG mode of operation, RST 103, DCG 104 and TX 105 are activated (turned ON) to remove charge from PD 106 to start a new exposure. During exposure, pixel 101 is an idle state, and charge accumulates across PD 106. RST 103, DCG 104 are asserted to reset node FD1 and node FD2. The pixel reset level (FD1 reset) is evaluated at pixel output node 112. TX 105 is asserted to transfer the PD charge to node FD1. When electrons are transferred, a voltage step is induced on node FD1 and pixel output node 112. The pixel output voltage level (after PD charge transfer) is evaluated at pixel output node 112 and stored. In some embodiments, correlated double sampling (CDS) operation is used to subtract the pixel reset voltage from the signal voltage of the pixel at the end of each integration period.

For LCG mode of operation, RST 103 and DCG 104 are activated (turned ON) to reset node FD1 and node FD2. The pixel reset voltage level is evaluated at pixel output node 112 and stored. TX 105 is asserted to transfer the PD charge to node FD1 and node FD2. When electrons are transferred, a voltage step is induced on node FD1, node FD2 and the pixel output node 112. The pixel output voltage (after PD charge transfer) is evaluated at pixel output node 112. CDS operation is used to subtract the pixel reset voltage from the signal voltage of the pixel at the end of each integration period.

### Modified Operation

With the conventional DCG pixel circuit operation described above, the pixel output voltage at pixel node 112 is input into a conventional ADC, which converts the analog voltage into a digital representation that can be processed by an ISP (not shown) in the digital domain. This results in HCG and LCG readouts for every pixel in the frame without accounting for the different intensities of the pixels. To reduce readout time and increase frame rate, ACGS-ADC 102 is a ramp-type ADC that has been modified to generate feedback signal coupled to the gate of DCG 104 to control whether HCG or LCG is activated on pixel 101 based on the intensity of pixel 101.

Referring again to FIG. 1, ACGS-ADC 102 includes multiplexer 121 and comparator 120. Multiplexer 121 includes three inputs: a CG selection enable signal (CGSEL_EN), a first input signal (DCG_GLBL) and the output of comparator 120. In some embodiments, comparator 120 is configured such that if Vₒᵤₜ is greater than V_{MAX}, the LGC mode is activated, otherwise the HGC mode is activated. V_{MAX} is a saturation limit of the pixel. The output of multiplexer 121 is a feedback signal that is asserted on feedback line 122 which is coupled to the gate of DCG 104, such that, on a pixel by pixel basis, either HCG or LCG mode is activated but not both.

In some embodiments, the output of multiplexer 121 depends on the value of CGSEL_EN. For example, if CGSEL is high, then input “1” is steered by multiplexer 121 to feedback line 122. If CGSEL is low, then input “0” is steered by multiplexer 121 to feedback line 122. If CGSEL is high, then an auto-select CG feature is enabled, if CGSEL is low, then auto-select CG is disabled and the pixel array can be operated same as the conventional operation. In some embodiments, DCG_GLBL is connected to ground, such that HCG mode is activated only for pixels that are not approaching their saturation limit. The purpose of the multiplexer 121 therefore is to enable conventional pixel operation on ACGS-ADC by setting CGSEL_EN=0. When CGSEL_EN=0, the column lines are controlled by the DCG_GLBL signal which globally selects all pixels to be either LCG or HCG mode, i.e., conventional operation.

In some embodiments, a gain bit may be added to the most significant bits (MSBs) to the output of ADC 102 during LCG mode to extend the dynamic range and quantization resolution of the image sensor. In some embodiments, non-readout rows are kept in anti-blooming configuration to avoid impact from toggling of the shared-DCG column.

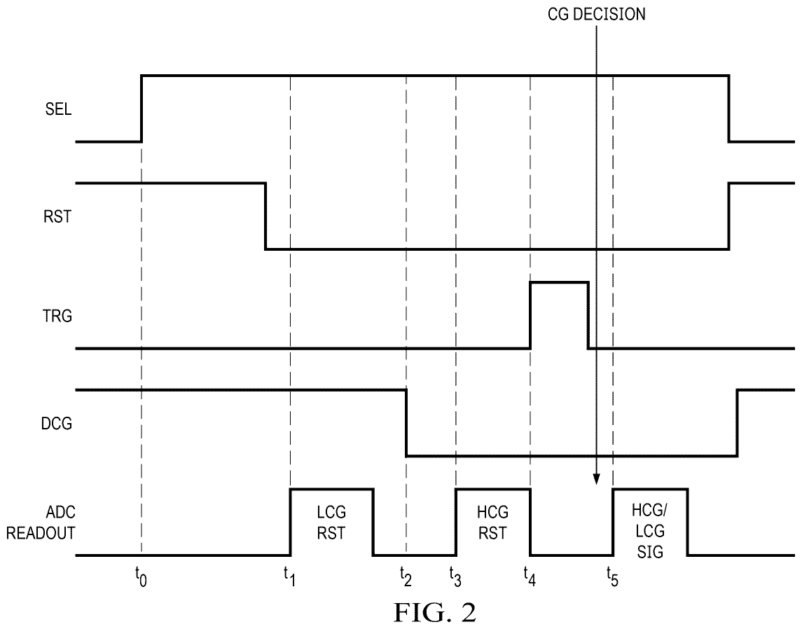

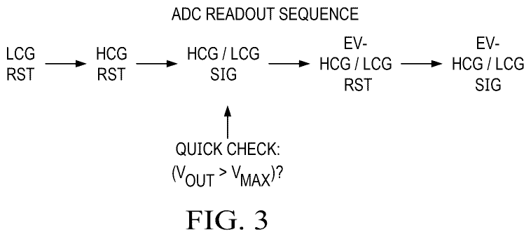

FIG. 2 is a timing diagram for the ACGS-ADC 102 shown in FIG. 1, according to one or more embodiments. FIG. 3 is an ADC readout sequence diagram corresponding to the schematic in FIG. 1 and timing diagram shown in FIG. 2, according to one or more embodiments.

Referring to FIGS. 1 and 2, at time t₀ a new exposure starts when SEL 111, RST 103 and DCG 104 are activated (turned ON) to reset nodes FD1 and FD2. At time t₁, the pixel reset voltage level for LCG (FD1+FD2) at pixel output node 112 is read out and evaluated by comparator 120 and stored in memory. At time t₂, DCG 104 is deactivated (turned OFF). At time t₃, the pixel reset voltage level for HCG (FD1) at pixel output node 112 is readout and evaluated by comparator 120 and stored in memory. At time t₄, TX 105 is activated to transfer the PD charge to node FD1. After charge transfer at time t₄, a CG decision is made by comparator 120 to determine if Vₒᵤₜ is greater than V_{MAX}. Based on this evaluation, at time t₅ either HCG or LCG mode (not both) is activated.

Regarding the CG decision prior to time t₅, if Vₒᵤₜ is greater than V_{MAX}, then pixel 101 is saturated and therefore there is no reason to do HCG readout. The selected mode is signaled by a feedback signal asserted on feedback line 122 to the gate of DCG 104. If the pixel is saturated, then LCG mode is active for the pixel. Otherwise, HCG mode is active for the pixel. This reduces number of CG readouts from two to one for saturated pixels, resulting in an increase in camera frame rate compared to the conventional method that performs both HCG and LCG readouts for every pixel regardless of the intensity of the pixel.

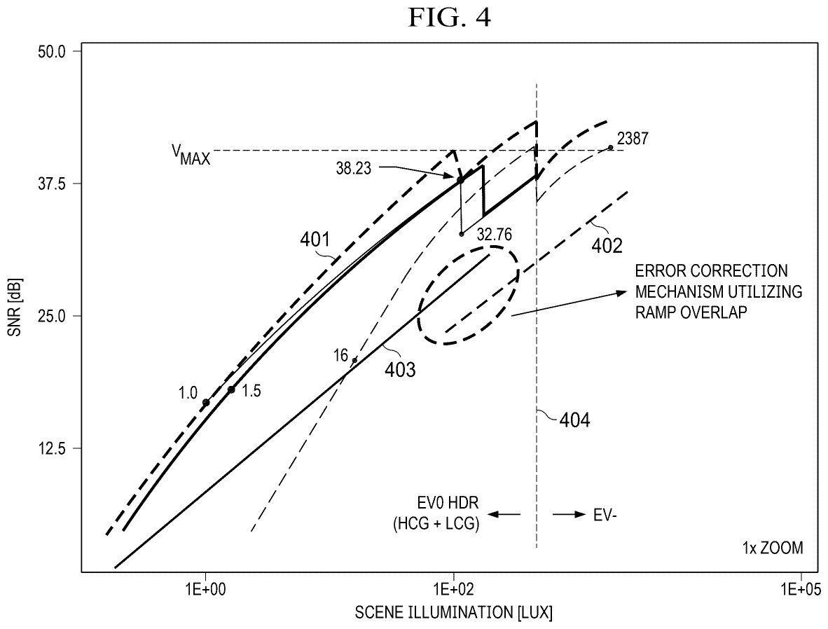

FIG. 4 illustrates image SNR plot for an adaptive CG operation together with a dual frame exposure and, an error correction mechanism utilizing ramp overlap, according to one or more embodiments. The SNR signal of the pixel 401 and the V_{MAX} limit is shown. The adaptive operation can cause comparator flip errors at the CG crossover point 404, which creates signal discontinuity and nonlinearity thereby creating artifacts in the image due to incorrect pixel intensity. To address this problem, overlapping ramps 402, 403 are generated by ramp generator 515 to create an overlap region, such that LCG begins before HCG ends. Utilizing a dual exposure, helps further enhance the achievable dynamic range with a DCG pixel.

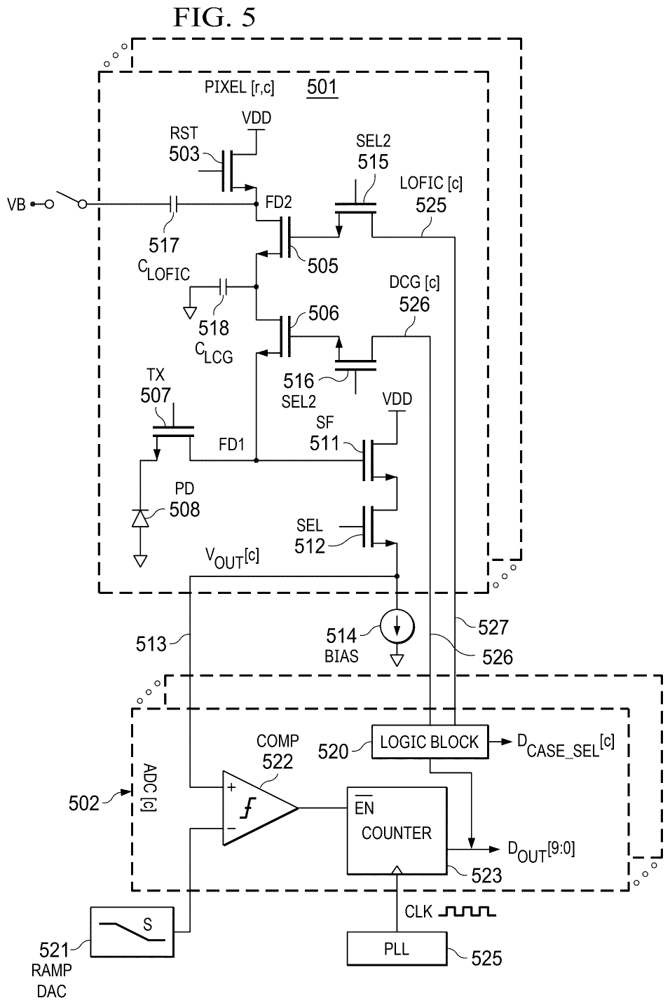

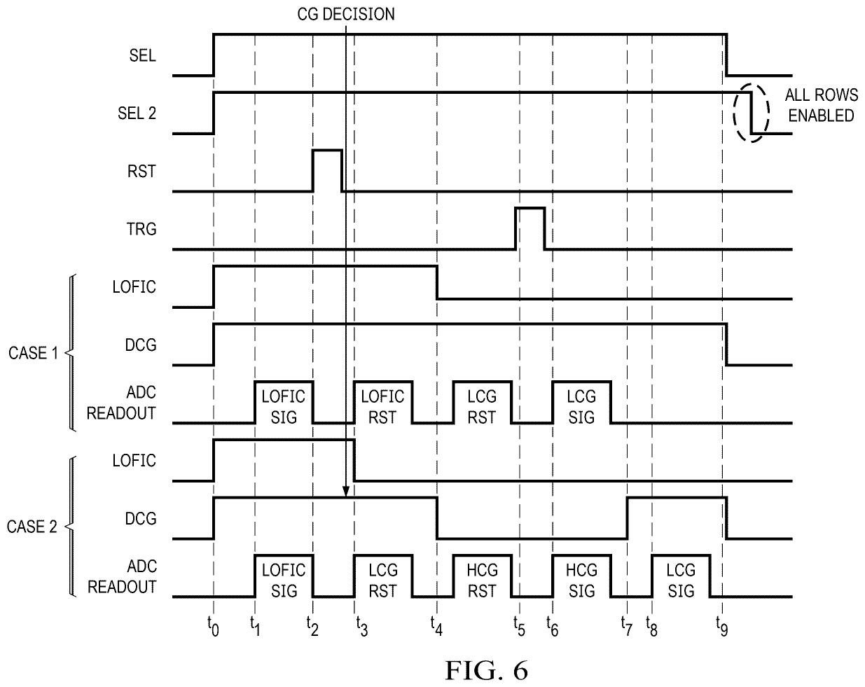

FIG. 5 is a schematic diagram of a column-level ACGS-ADC 502 for an example TCG pixel architecture, according to one or more embodiments. Pixel circuit 501 is a triple conversion gain (TCG) pixel with has three CG modes of operation: Low (LOFIC), Medium (LCG) and High (HCG). Conventional operation of pixel circuit 501 includes 3 sequential readouts: LOFIC followed by HCG followed by LCG, and typically requires more and faster ADCs. The modified operation of pixel 501 includes automatic pixel readout based on LOFIC signal sampling, which reduces the number of sequential readouts from 3 to 2, thereby increasing the camera frame rate. Two cases are shown in FIG. 6. In Case 1, a LOFIC readout is followed by an LCG readout. In Case 2, an LCG readout is followed by an HCG readout.

ACGS-ADC 502 is shown coupled to pixel output node 513 of pixel 501. In the example shown, only a single pixel 501 and ACGS-ADC 502 are shown. A CMOS image sensor, however, comprises a two-dimensional array of pixels 501 arranged in rows and columns. The image sensor includes analog “readout” circuitry (not shown) that is configured to readout each column [c] of pixels by selecting the individual rows [r] of the column [c] in and ordered sequence. Each column [c] is coupled to its own ACGS-ADC 502 for converting the analog output voltage (Vₒᵤₜ) at pixel output node 513 to a digital representation (D_{OUT}[]) that is processed in the digital domain by, e.g., an image signal processor (ISP).

Pixel 501 includes reset transistor (RST) 503, LOFIC transistor 505, DCG transistor 506, transfer gate (TX) 507, photodiode (PD) 508, first floating diffusion node (FD1), second floating diffusion node (FD2), source follower 511, row selection transistor (SEL) 512, pixel output node 513, current source 514, LOFIC selection transistor (SEL2) 515, DCG selection transistor 516 (SEL2), charge storage capacitor 517 (C_{LOFIC}), charge storage capacitor 518 (C_{LCG}). The selection transistors 515, 516 avoid charge redistribution on non-selected rows. A periodic global SEL2 activation allows any spurious charge on the gates of non-selected LOFIC 506 or DCG 505 to be flushed.

Note that while the TCG pixel architecture described above and below utilizes a LOFIC, the HDR pixel conversion gains can be implemented by utilizing different or similar types of charge storage elements. For example, charge storge capacitors 517, 518 can be parasitic capacitance, metal-insulator-metal capacitance, metal-oxide-semiconductor capacitance etc.

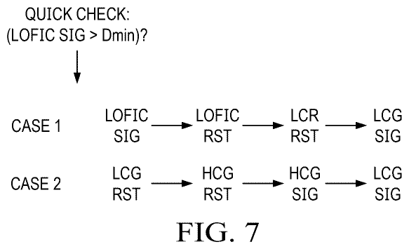

ACGS-ADC 502 includes logic block 520, ramp generator 521, comparator 522, counter 523, and clock pulse generator 525. Logic block 520 is coupled to the output of counter 523. Logic block 520 asserts a DCG feedback signal on feedback line 526 which is coupled by selection transistor 516 to the gate of DCG transistor 506 for activating/deactivating DCG transistor 506, and a LOFIC feedback signal on feedback line 527 which is coupled by selection transistor 515 to the gate of LOFIC transistor 505, for activating/deactivating LOFIC transistor 505, respectively, based on the outputs of logic block 520. Logic block 520 also outputs a case selection bit (D_{CASE_SEL}[c]) which indicates whether Case 1 or Case 2 is active, as described in reference to FIGS. 6 and 7. This bit (0 or 1) determines the digital gain to be applied to the ADC output to scale the output to the right intensity level.

All of the elements described above operate in a similar manner as their counterpart elements in FIG. 1. Additional elements in this embodiment include LOFIC selection transistor 515, DCG selection transistor 516, charge storage capacitor 517, charge storage capacitor 518, and logic block 520. LOFIC selection transistor 515 gates feedback signal 527 and DCG selection transistor 516 gates feedback signal 526. Logic block 520 contains digital logic to decide whether to pursue Case1 or Case2 pixel timing. Then logic block 520 takes input the digitized M-bit value (e.g., M=10) from counter 523 and compares it against a specified M-bit digital value called Dₘᵢₙ. Based on this comparison decision (high or low), logic block 520 decides whether to pursue case 1 or case 2 timing.

FIG. 6 is a timing diagram for the ACGS-ADC 502 shown in FIG. 5, according to one or more embodiments. FIG. 7 is an ADC readout sequence diagram corresponding to the timing diagram in FIG. 6. There are two cases illustrated in FIGS. 6 and 7. After initial LOFIC signal conversion at time t₁, the logic block decides whether to pursue Case 1 or Case 2. In Case 1, HCG and LCG readouts are performed, and in Case 2 LCG and LOFIC readouts are performed.

### Case 1

At time t₀, SEL 512, gate selection transistors 515, 516 are activated, the DCG and LOFIC activation signals are asserted on feedback lines 526 and 527, respectively, activating (opening) the gates on DCG transistor 505 and LOFIC transistor 506, respectively. At time t₁, the LOFIC signal is readout. At time t₂, reset transistor 503 is asserted. Prior to time t₃, a CG decision is made by logic 520 based on whether the sampled LOFIC signal level is greater than Dₘᵢₙ. At time t₃, the LOFIC reset level is read out. A time t₄ LOFIC transistor 506 is deactivated. At time t₅, transmission gate 507 is activated. At time t₆, the LCG signal is readout. At time t₉, DCG transistor 505 is deactivated.

### Case 2

At time t₀, row selection transistor 512, gate selection transistors 515, 516 are activated, the DCG and LOFIC feedback signals are asserted on feedback lines 526 and 527, respectively, activating (opening) the gates on DCG transistor 505 and LOFIC transistor 506, respectively. At time t₁, the LOFIC signal is readout. At time t₂, the reset transistor 503 is asserted. Prior to time t₃, a CG decision is made by logic 520 based on whether the LOFIC signal level is greater than Dmin. At time t₃, the LCG reset level is read out. A time t₄, the DCG transistor 505 is deactivated. At time t₅, transmission gate 507 is activated. At time t₆, the HCG signal is readout. At time t₇, the DCG transistor 505 is activated. At time t₈, the LCG signal is read out. At time t₉, DCG transistor 505 is deactivated.

Note that high density LOFIC capacitors suffer from memory effect. The purpose of the VB switch is to efficiently flush any residual charge stored on the LOFIC capacitor, thereby preventing it from being carried over to the next image frame. This operation is performed both for Case 1 and Case 2.

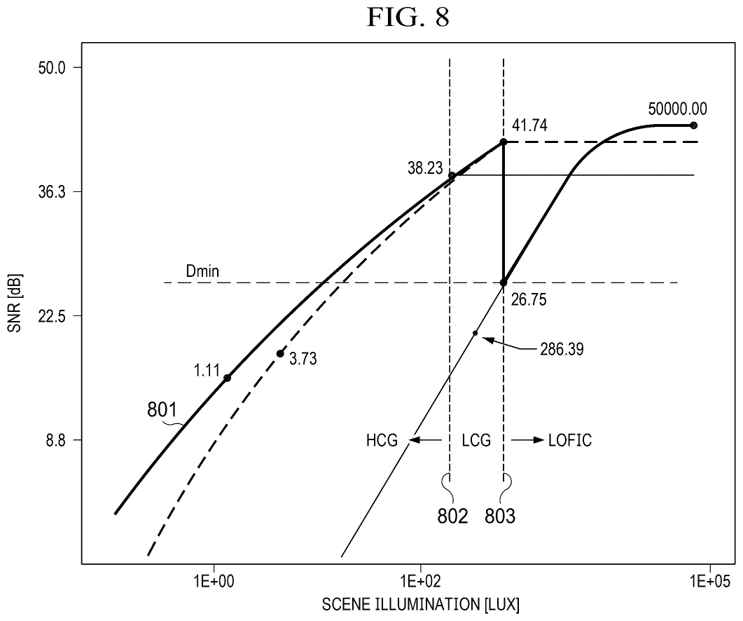

FIG. 8 illustrates pixel SNR versus scene illumination for the three conversion gain modes (HCG, LCG and LOFIC), according to one or more embodiments. This graph is divided into three activation regions: HCG, LCG and LOFIC activation regions. The SNR signal 801 is plotted. CG cross-over points 802, 803 are also shown. At CG cross-over point 802, ACGS-ADC 502 transitions from HCG to LCG. At CG cross-over point 803, ACGS-ADC 502 transitions from LCG to LOFIC. As the first step, the LOFIC signal value is quantized and its digital value is compared against a set value Dₘᵢₙ. If the LOFIC signal is lower than Dₘᵢₙ, it implies that the LOFIC SNR is below a threshold for image blending and therefore is not utilized for image blending. Therefore, Case 1 is pursued with HCG and LCG gain conversion followed by image blending. If the LOFIC signal is higher than Dₘᵢₙ, then it implies that the LOFIC signal has sufficient SNR, and the HCG signal is saturated. Therefore, Case 2 is followed, where HCG signal conversion is skipped and only LCG and LOFIC signals are converted.

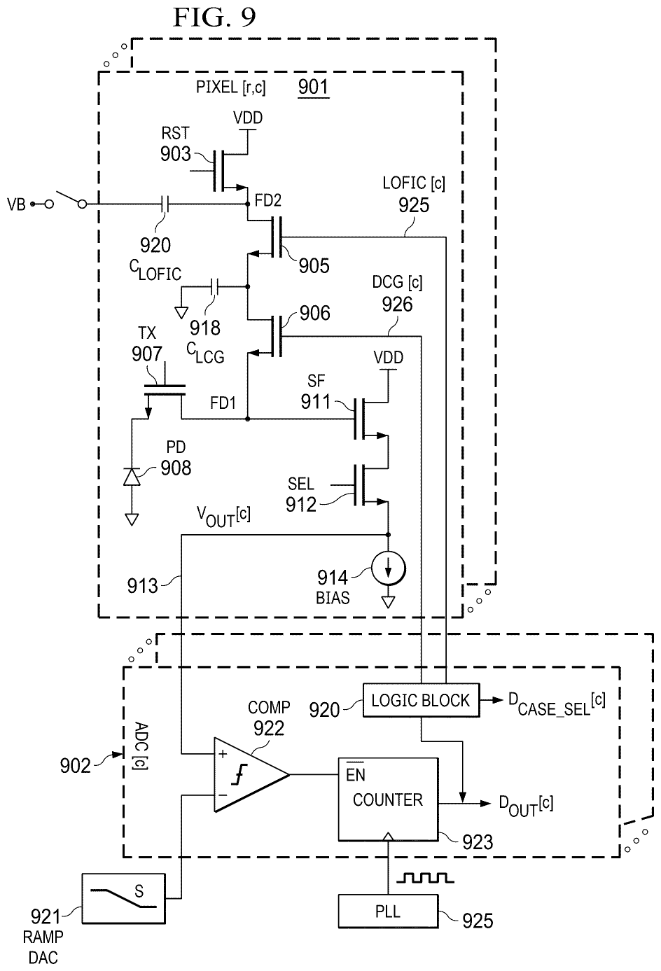

FIG. 9 is schematic diagram of a column-level ACG-ADC 902 for an alternative TCG pixel architecture, according to one or more embodiments. FIG. 9 is a TCG pixel architecture similar to the TCG pixel architecture shown in FIG. 5, but without LOFIC selection transistor 515 and DCG selection transistor 516.

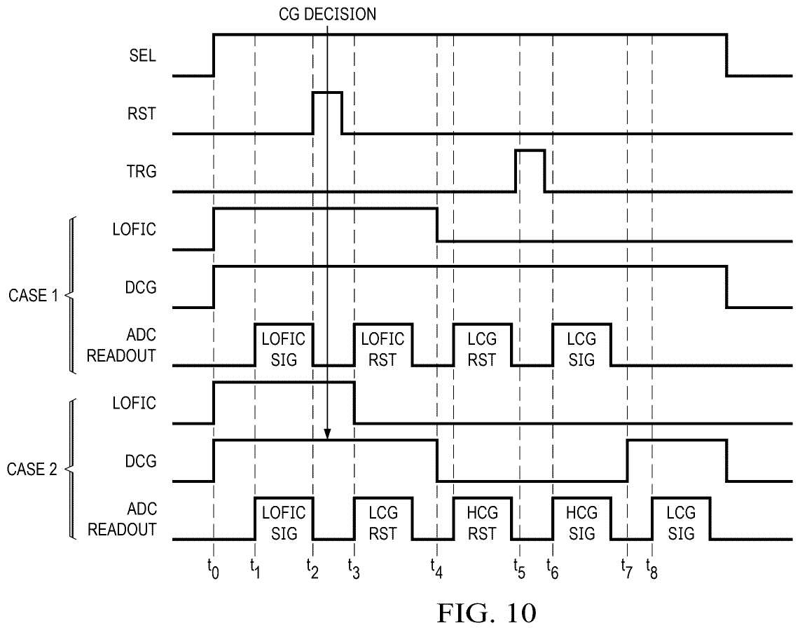

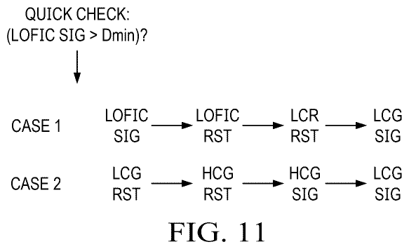

FIG. 10 is a timing diagram for the ACG-ADC shown in FIG. 9, according to one or more embodiments. FIG. 11 is an ADC readout sequence diagram corresponding to the timing diagram shown in FIG. 10, according to one or more embodiments.

### Case 1

At time t₀, SEL 512 is activated, DCG transistor 505 is deactivated and LOFIC transistor 506 is activated. At time t₁, the LOFIC signal is readout. At time t₂, the reset transistor 503 (RST), is activated. Prior to time t₃, a CG decision is made by logic 520 based on whether the LOFIC signal level is greater than Dₘᵢₙ (see FIG. 8). At time t₃, the LOFIC reset level is read out. A time t₄ LOFIC transistor 506 is deactivated. At time t₅, transmission gate 507 is activated. At time t₆, the LCG signal is readout. At time t₇, DCG transistor 505 is activated.

### Case 2

At time t₀, row selection transistor (SEL) 512, gate selection transistors (SEL2) 515, 516 are activated, the DCG and LOFIC feedback signals are asserted on feedback lines 526 and 527, respectively, opening the gates on DCG transistor 505 and LOFIC transistor 506, respectively. At time t₁, the LOFIC signal is readout. At time t₂, the reset transistor 503 (RST) is asserted. Prior to time t₃, a CG decision is made by logic 520 based on whether the LOFIC signal level is greater than Dₘᵢₙ. At time t₃, LOFIC transistor 506 is deactivated and the LCG reset level is read out. At time t₄, the DCG transistor 505 is deactivated. At time t₅, transmission gate 507 is activated. At time t₆, the HCG signal is readout. At time t₇, the DCG transistor 505 is activated. At time t₈, the LCG signal is read out.

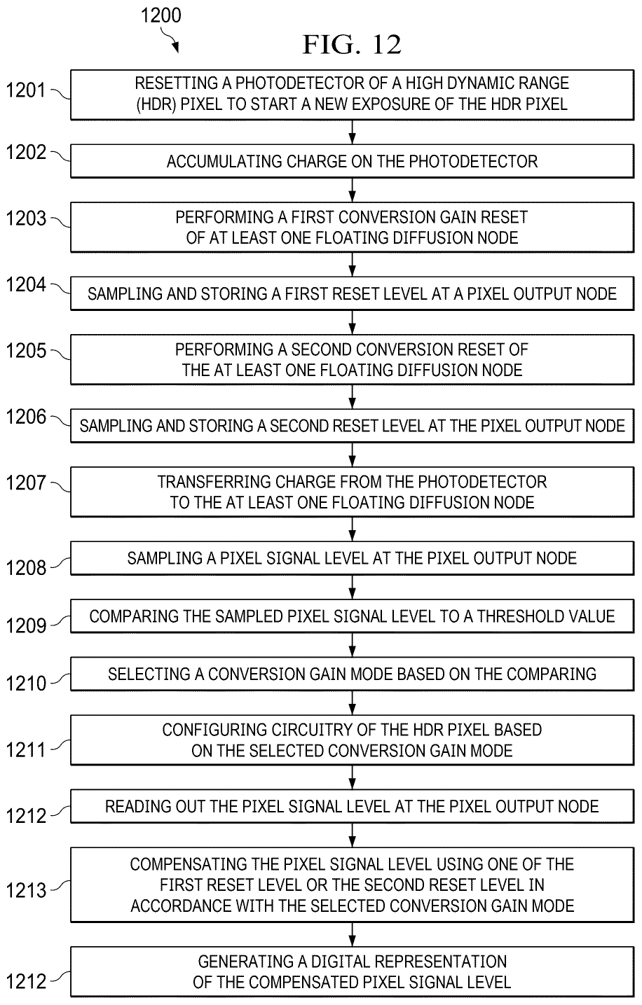

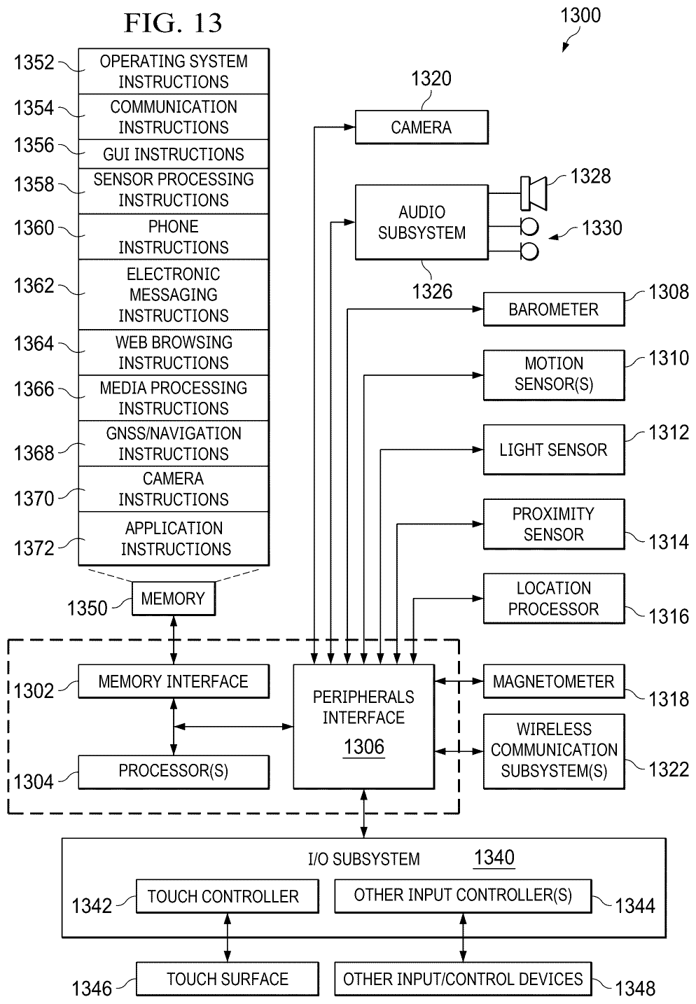

FIG. 12 illustrates a process 1200, according to one or more embodiments. Process 1200 can be implemented using, for example, the device architecture 1300 shown in FIG. 13.

Process 1200 includes resetting a photodetector of a high dynamic range (HDR) pixel to start a new exposure of the HDR pixel (1201); accumulating charge on the photodetector (1202); performing a first conversion gain reset of at least one floating diffusion node (1203); sampling and storing a first reset level at a pixel output node (1204); performing a second conversion reset of the at least one floating diffusion node (1205); sampling and storing a second reset level at the pixel output node (1206); transferring charge from the photodetector to the at least one floating diffusion node (1207); sampling a pixel signal level at the pixel output node (1208); comparing the sampled pixel signal level to a threshold value (1209); selecting a conversion gain mode based on the comparing (1210); configuring circuitry of the HDR pixel based on the selected conversion gain mode (1211); reading out the pixel signal level at the pixel output node (1212); compensating the pixel signal level using one of the first reset level or the second reset level in accordance with the selected conversion gain mode (1213); and generating a digital representation of the compensated pixel signal level (1214). Each of these steps was described in detail in reference to FIGS. 1-11.

### Example Device Architecture

FIG. 13 is a conceptual block diagram of device architecture 1300 implementing the features and operations described in reference to FIGS. 1-12. Architecture 1300 can include memory interface 1302, one or more data processors 1304 (e.g., digital signal processors (DSPs), central processing units (CPUs)) and peripherals interface 1306. Memory interface 1302, one or more data processors 1304 and/or peripherals interface 1306 can be separate components or can be integrated in one or more integrated circuits.

Sensors, devices and subsystems can be coupled to peripherals interface 1306 to provide multiple functionalities. For example, one or more motion sensors 1310, light sensor 1312 and proximity sensor 1314 can be coupled to peripherals interface 1306 to facilitate motion sensing (e.g., acceleration, rotation rates), lighting and proximity functions of the wearable computer. Location processor 1316 can be connected to peripherals interface 1306 to provide geo-positioning. In some implementations, location processor 1316 can be a GNSS receiver, such as the Global Positioning System (GPS) receiver. Electronic magnetometer 1318 (e.g., an integrated circuit chip) can also be connected to peripherals interface 1306 to provide data that can be used to determine the direction of magnetic North. Electronic magnetometer 1318 can provide data to an electronic compass application. Motion sensor(s) 1310 can be an IMU that includes one or more accelerometers and/or gyros (e.g., 3-axis MEMS accelerometer and 3-axis MEMS gyro) configured to determine change of speed and direction of movement of the source device. Barometer 1308 can be configured to measure atmospheric pressure around the mobile device.

Camera 1320 captures digital images and video and can include both forward-facing and rear-facing cameras.

Communication functions can be facilitated through wireless communication subsystems 1322, which can include radio frequency (RF) receivers and transmitters (or transceivers) and/or optical (e.g., infrared) receivers and transmitters. The specific design and implementation of the wireless communication subsystem 1322 can depend on the communication network(s) over which a mobile device is intended to operate. For example, architecture 1300 can include communication subsystems 1322 designed to operate over a GSM network, a GPRS network, an EDGE network, a Wi-Fi™ network and a Bluetooth™ network. In particular, the wireless communication subsystems 1322 can include hosting protocols, such that the mobile device can be configured as a base station for other wireless devices.

Audio subsystem 1326 can be coupled to a speaker 1328 and one or more microphones 1330 to facilitate voice-enabled functions, such as voice recognition, voice replication, digital recording and telephony functions. Audio subsystem 1326 can be configured to receive voice commands from the user.

I/O subsystem 1340 can include touch controller 1342 and/or other input controller(s) 915. Touch controller 1342 can be coupled to a touch surface 1346. Touch surface 1346 and touch controller 1342 can, for example, detect contact and movement or break thereof using any of a plurality of touch sensitivity technologies, including but not limited to capacitive, resistive, infrared and surface acoustic wave technologies, as well as other proximity sensor arrays or other elements for determining one or more points of contact with touch surface 1346. Touch surface 1346 can include, for example, a touch screen or the digital crown of a smart watch. I/O subsystem 1340 can include a haptic engine or device for providing haptic feedback (e.g., vibration) in response to commands from data processor(s) 1304. In an embodiment, touch surface 1346 can be a pressure-sensitive surface.

Other input controller(s) 1344 can be coupled to other input/control devices 1348, such as one or more buttons, rocker switches, thumb-wheel, infrared port and USB port. The one or more buttons (not shown) can include an up/down button for volume control of speaker 1328 and/or microphones 1330. Touch surface 1346 or other input control devices 1348 (e.g., a button) can include, or be coupled to, fingerprint identification circuitry for use with a fingerprint authentication application to authenticate a user based on their fingerprint(s).

In one implementation, a pressing of the button for a first duration may disengage a lock of the touch surface 1346; and a pressing of the button for a second duration that is longer than the first duration may turn power to the mobile device on or off. The user may be able to customize a functionality of one or more of the buttons. The touch surface 1346 can, for example, also be used to implement virtual or soft buttons.

In some implementations, the mobile device can present recorded audio and/or video files, such as MP3, AAC and MPEG files. In some implementations, the mobile device can include the functionality of an MP3 player. Other input/output and control devices can also be used.

Memory interface 1302 can be coupled to memory 1350. Memory 1350 can include high-speed random access memory and/or non-volatile memory, such as one or more magnetic disk storage devices, one or more optical storage devices and/or flash memory (e.g., NAND, NOR). Memory 1350 can store operating system instructions 1352, such as the iOS operating system developed by Apple Inc. of Cupertino, California. Operating system instructions 1352 may include instructions for handling basic system services and for performing hardware dependent tasks. In some implementations, operating system instructions 1352 can include a kernel (e.g., UNIX kernel).

Memory 1350 may also store communication instructions 1354 to facilitate communicating with one or more additional devices, one or more computers and/or one or more servers, such as, for example, instructions for implementing a software stack for wired or wireless communications with other devices. Memory 1350 may include graphical user interface (GUI) instructions 1356 to facilitate graphic user interface processing; sensor processing instructions 1358 to facilitate sensor-related processing and functions; phone instructions 1360 to facilitate phone-related processes and functions; electronic messaging instructions 1362 to facilitate electronic-messaging related processes and functions; web browsing instructions 1364 to facilitate web browsing-related processes and functions; media processing instructions 1366 to facilitate media processing-related processes and functions; GNSS/Location instructions 1368 to facilitate generic GNSS and location-related processes; and camera instructions 1370 for capturing images (e.g., video, still images) and performing the operations described in reference to FIGS. 1-12. Memory 1350 further includes application instructions 1372 for use in various applications, including but not limited applications that utilize HDR images generated as described in reference to FIGS. 1-12.

Each of the above identified instructions and applications can correspond to a set of instructions for performing one or more functions described above. These instructions need not be implemented as separate software programs, procedures, or modules. Memory 1350 can include additional instructions or fewer instructions. Furthermore, various functions of the mobile device may be implemented in hardware and/or in software, including in one or more signal processing and/or application specific integrated circuits.

While this specification contains many specific implementation details, these should not be construed as limitations on the scope of any inventions or of what may be claimed, but rather as descriptions of features specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable sub combination. Moreover, although features may be described above as acting in certain combinations and even initially claimed as such, one or more features from a claimed combination can in some cases be excised from the combination, and the claimed combination may be directed to a sub combination or variation of a sub combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

What is claimed is:

1. A method comprising:
resetting a photodetector of a high dynamic range (HDR) pixel of an image sensor to start a new exposure of the HDR pixel, where the HDR pixel has at least two conversion gain modes;
accumulating charge on the photodetector;
performing a first conversion gain reset of at least one floating diffusion node;
sampling and storing a first reset level at a pixel output node;
performing a second conversion reset of the at least one floating diffusion node;
sampling and storing a second reset level at the pixel output node;
transferring charge from the photodetector to the at least one floating diffusion node;
sampling a pixel signal level at the pixel output node;
comparing the sampled pixel signal level to a threshold value;
selecting a conversion gain mode based on the comparing;
configuring circuitry of the HDR pixel based on the selected conversion gain mode;
reading out the pixel signal level at the pixel output node;
compensating the pixel signal level using one of the first reset level or the second reset level in accordance with the selected conversion gain mode; and
generating a digital representation of the compensated pixel signal level.

2. The method of claim 1, wherein the HDR pixel is a dual conversion gain (DCG) pixel and the threshold value is an arbitrary set value or a saturation limit of the photodetector.

3. The method of claim 2, wherein selecting a conversion gain mode based on the comparing further comprises:
inputting the sampled pixel signal into an analog-to-digital converter (ADC) that includes a comparator for comparing the sampled pixel signal with a reference signal level;
determining that an output of the comparator is greater than the saturation limit; and
generating a feedback signal for the HDR pixel, the feedback signal configuring circuity in the HDR pixel to select a low conversion gain (LCG) mode.

4. The method of claim 3, where the ADC is a ramp-type ADC and the method further comprises:
determining a comparator flip error; and
compensating for the comparator flip error.

5. The method of claim 1, further comprising appending gain bits to the digital representation during the LCG mode to extend the dynamic range and quantization resolution of the image sensor.

6. The method of claim 1, wherein non-readout rows of the pixel are kept in anti-blooming configuration to avoid impact from toggling of a shared column of the pixel.

7. The method of claim 1, wherein the HDR pixel is a triple conversion gain (TCG) pixel with three conversion gain modes, including a low conversion gain (LCG) mode, a high conversion gain (HCG) mode and a LOFIC conversion gain mode, and wherein the TCG pixel performs two sequential readouts of the pixel signal level.

8. The method of claim 1, wherein the HDR pixel is a triple conversion gain (TCG) pixel with three conversion gain modes, including a low conversion gain (LCG) mode, a high conversion gain (HCG) mode and a medium conversion gain (MCG) mode, and wherein the TCG pixel performs two sequential readouts of the pixel signal level.

9. The method of claim 1, wherein the HDR pixel conversion gains are implemented utilizing at least one of parasitic capacitance, metal-insulator-metal capacitance, or metal-oxide-semiconductor capacitance.

10. The method of claim 7, wherein selecting a conversion gain mode based on the comparing further comprises:
inputting the sampled pixel signal into an analog-to-digital converter (ADC) that includes a comparator for comparing the sampled pixel signal with a reference signal level;
determining that an output of the comparator is greater than a specified threshold; and
generating two feedback signals for the HDR pixel, the two feedback signals configuring circuitry in the HDR pixel to select one of the LCG, HCG or LOFIC conversion gain mode.

11. The method of claim 10, where the ADC is a ramp-type ADC and the method further comprises:
determining a comparator flip error; and
compensating for the comparator flip error.

12. The method of claim 10, further comprising appending gain bits to the output of ADC during the LCG mode to extend the dynamic range and quantization resolution of the image sensor.

13. The method of claim 10, wherein the circuitry of the HDR pixel is configured to readout a LOFIC pixel signal, followed by a readout of a LOFIC reset level, followed by a readout of a LCG reset level, followed by a readout of a LCG pixel signal.

14. The method of claim 10, wherein the circuitry of the HDR pixel is configured to readout a sampled LCG reset level, followed by a readout of a HCG reset level, followed by a readout of a HCG pixel signal, followed by a readout of a LCG pixel signal.

15. The method of claim 1, wherein the pixel is operated with two or more successive exposures followed by image blending to further enhance its dynamic range.

16. An analog-to-digital converter (ADC) comprising:
a reference signal generator configured to generator a reference signal;
a clock pulse generator configured to generate a clock;
a comparator configured to compare the reference signal and a pixel signal readout from a high dynamic range (HDR) pixel, where the HDR pixel has a low conversion gain (LCG) mode and a high conversion gain (HCG) mode;
a counter coupled to the output of the comparator and to the clock, the counter configured to start counting in response to the output of the comparator and the clock, the counter outputting a digital representation of the pixel signal; and
a logic block configured to compare the output of the comparator to a saturation limit of the HDR pixel and generate a feedback signal to the HDR pixel, the feedback signal for configuring circuitry of the HDR pixel to select one of the HCG mode or the LCG mode based on whether the output of the comparator exceeds the saturation limit.

17. The ADC of claim 16, wherein the reference signal generator is a ramp generator and the reference signal is a ramp signal.

18. The ADC of clam 16, wherein the logic block generates gain bits to be appended with the digital representation during the LCG mode to extend the dynamic range and quantization resolution of an image sensor.

19. An analog-to-digital converter (ADC) comprising:
a reference signal generator configured to generator a reference signal;
a clock pulse generator configured to generate a clock;
a comparator configured to compare the reference signal and a pixel signal readout from a high dynamic range (HDR) pixel, where the HDR pixel has a low conversion gain (LCG) mode, a high conversion gain (HCG) mode and a lateral overflow integrating capacitor (LOFIC) conversion mode, and the pixel signal is a sampled LOFIC signal;
a counter coupled to the output of the comparator and to the clock, the counter configured to start counting in response to the output of the comparator and the clock, the counter outputting a digital representation of the pixel signal; and
a logic block configured to compare the output of the comparator to a threshold value and generate two feedback signals to the HDR pixel, the two feedback signals for configuring circuitry of the HDR pixel to select one of the HCG mode, the LCG mode or the LOFIC conversion gain mode based on whether the output of the comparator exceeds the threshold value.

20. The ADC of claim 19, wherein the reference signal generator is a ramp generator and the reference signal is a ramp signal.

21. The ADC of clam 19, wherein the two feedback signals configure circuitry in the HDR pixel to select one of two ADC readout sequences, a first readout sequence comprising: readout of a LOFIC signal, followed by readout of a LOFIC reset level, followed by readout of an LCG reset level, followed by readout of an LCG signal, and a second readout sequence comprising: readout of an LCG reset level, followed by readout of an HCG reset level, followed by readout of an HCG signal, followed by readout of an LCG signal.

22. The ADC of clam 19, wherein the logic block generates a bit indicating the selected ADC readout sequence.

23. An image sensor comprising:
a pixel array comprising rows and columns of high dynamic range (HDR) pixels, each HDR pixel including circuitry for processing charge accumulated on a photodiode of the HDR pixel when exposed to light and selection circuitry for selecting one of at least two conversion gain modes for readout of the HDR pixels;
readout circuitry configured to readout each column of the pixel array by selecting each row of the pixel array in a sequence in accordance with the selected conversion gain mode;
an analog-to-digital converter (ADC) coupled to each column of the pixel array, each ADC comprising:
a comparator configured to compare a reference signal and a pixel signal readout from an HDR pixel in accordance with the selected conversion mode;
a counter coupled to the output of the comparator and to the clock, the counter configured to start counting in response to the output of the comparator and the clock, the counter outputting a digital representation of the pixel signal; and
a logic block coupled to selection circuitry of the HDR pixel, the logic block configured to compare the output of the comparator to a saturation limit or threshold value and to generate at least one feedback signal to the HDR pixel for configuring the selection circuitry of the HDR pixel based on whether the output of the comparator exceeds the saturation limit or threshold value.
